(19) United States
(12) Patent Application Publication
(10) Pub. No.: US 2015/0369453 A1
(43) Pub. Date: Dec. 24, 2015

(54) OLED/QLED LIGHT MODULE

(71) Applicant: TRIDONIC GMBH & CO. KG, Dornbirn (AU)

(72) Inventors: Michael ERITT, Dresden (DE); Christian KIRCHHOF, Dresden (DE); Tino GOEHLER, Dippoldiswalde (DE)

(21) Appl. No.: 14/654,375

(22) PCT Filed: Dec. 16, 2013
(86) PCT No.: PCT/EP2013/076693

§ 371 Date: Jun. 19, 2015

(30) Foreign Application Priority Data
Dec. 20, 2012 (DE) 10 2012 223 967.7

(51) Int. Cl. F21V 13/04; F21V 5/02; F21K 99/00

(52) U.S. Cl. CPC F21V 13/04; F21K 9/50; F21V 5/02; F21Y 2105/008

(57) ABSTRACT

A light module having a plate-shaped active element, which is formed by an OLED or QLED, and a plate-shaped, transparent carrier element having a surface on which the active element is arranged. The carrier element has an edge region that protrudes in relation to the active element. An optical element is arranged on a side of the carrier element opposite the active element and is designed to form a light-emitting area of the light module, which is widened compared to the area of the active element.

The present invention relates to a light module according to the preamble of claim 1, comprising a plate-shaped active element for emitting light, wherein the active element can be in particular a so-called OLED or QLED.

The development of so-called organic light emitting diodes (OLEDs) in recent years allows novel surface light elements to be realized, that is to say light sources which emit light across a relatively large area. As a planar illuminant having a moderate luminance in comparison with a traditional LED based on a semiconductor, an OLED is ideally suited to realizing relatively large diffusely emitting light sources, thereby opening up totally novel areas of application. Comparable advantages are also afforded in the case of so-called QLEDs (quantum dots light emitting diodes).

When realizing light modules on the basis of OLEDs, provision is usually made for the so-called active element formed by the OLED to be arranged on a plate-shaped substrate. In order to protect the OLED material against external influences, a so-called encapsulation generally takes place, that is to say that the active element is not only covered by a substrate or other planar elements at its two flat sides, but is also correspondingly enclosed in its edge region. This can be achieved, for example, by the substrate having a slight depression in which the OLED is then arranged.

Irrespective of the manner in which the active element is encapsulated, however, this leads to a non-luminous edge region extending circumferentially or at least partly surrounding the active element. That is to say that, as viewed in terms of area, the light module occupies a somewhat larger dimensioning than that area over which light is actually emitted. This leads to certain limits with regard to a homogeneous light emission for the case where a plurality of light modules are arranged alongside one another in order jointly to form a larger light emitting area, since darker locations then occur in the transition regions between two light modules.

The present invention therefore addresses the problem of specifying a further development of previously known light modules based on OLEDs or QLEDs in which a light emission can be achieved as far as possible across the entire extent of the light module.

The problem is solved by means of a light module comprising the features of claim 1. The dependent claims relate to advantageous developments of the invention.

With regard to its construction, the light module according to the invention initially corresponds to a traditional OLED- or QLED-based light module. That is to say that the light module initially comprises a plate-shaped active element, which can be formed in particular by an OLED or QLED. Furthermore, a plate-shaped, light-transmissive carrier element is provided, having a surface on which the active element is arranged, wherein the carrier element has an edge region that projects with respect to the active element. According to the invention, an additional optical element is now arranged on the opposite side of the carrier element relative to the active element, said optical element being designed to form a light emission area of the light module, wherein the light emission area brought about by the optical element is extended relative to the area of the active element. In other words, by virtue of the use of an additional optical element, the area over which the light emission of the light module is ultimately effected is enlarged in comparison with the active element, wherein ideally the light exit area corresponds to the maximum extent of the carrier element with regard to its extent. This ultimately means that, despite encapsulation of the active element, a light emission can be effected right into the edge region of the light module and light modules can accordingly be combined with one another in a planar fashion, without non-luminous interspaces occurring in this case.

The invention accordingly proposes a light module, comprising a plate-shaped active element, which is formed in particular by an OLED or QLED, and a plate-shaped, light-transmissive carrier element having a surface on which the active element is arranged, wherein the carrier element has an edge region that projects with respect to the active element. The light module according to the invention is characterized by an optical element, which is arranged on an opposite side of the carrier element relative to the active element and is designed to form a light emission area of the light module, which light emission area is extended relative to the area of the active element and preferably corresponds to the area of the carrier element with regard to its extent.

The optical element according to the invention is preferably embodied in a plate-like fashion and provided with a light entrance area facing the carrier element and with the light emission area opposite the light entrance area, wherein the light emission area preferably has a larger extent than the light entrance area. In particular, provision can be made for the light entrance area of the optical element to correspond substantially to the area of the active element with regard to its extent. Therefore, as viewed in a transverse direction, the optical element constitutes a type of optical waveguide which distributes the light entering via the carrier element in terms of area and then emits it via the light emission area. For this purpose, the optical element can be embodied for example in a trapezoidal or frustoconical fashion in cross section. As an alternative thereto, provision can also be made for the flat sides of the optical element to be connected to one another via side or edge regions which have a curvature at least in part. The side regions of the optical element which connect the two flat sides to one another have a reflective effect, which can be achieved either through a suitable choice of the angle in such a way that total internal reflection takes place here, or by a reflective coating being applied.

In order to be able to further improve the light emission via the light emission area of the optical element, provision can furthermore be made for a diffuser layer to be arranged between the carrier element and the optical element. Possible inhomogeneities of the active element with regard to the light emission can additionally be compensated for by this means. Furthermore, the light exit area of the optical element according to the invention can additionally be provided with a light-influencing structure, wherein either a scattering structure or a light-refracting structure, for example a prism structure or the like, can be involved.

Finally, in accordance with a further preferred embodiment of the invention, a structuring of the active element can also be provided in order to further improve the light emission. This is because, on account of the current density distributions that arise during the operation of OLEDs or QLEDs, a different luminance often occurs within the luminous area, which usually has the consequence that the active element is less brightly luminous in the center of the area than at the edge. In accordance with a first preferred development, therefore, provision is made for the active element to be structured or subdivided into a plurality of luminous and non-luminous regions, wherein preferably the luminous regions are driven uniformly. As a result of a corresponding arrangement or distribution of the luminous regions, it is then possible to achieve the effect that the average luminance at the edge corresponds to the average luminance in the central region of the active element. For this purpose, it is possible to increase e.g. the density of the luminous regions in the central region, in which a somewhat lower current density is generally present in the case of a completely homogeneous or closed active element. Another possibility for further improving the uniformity of the brightness of the active element consists in the latter being subdivided into at least two regions that are drivable separately from one another. In this case, the subdivision can be performed in particular in such a way that a central region and an edge region, which is drivable separately therefrom, are present, wherein non-uniformities in luminance can once again be compensated for by corresponding driving of both regions.

The invention will be explained in greater detail below with reference to the accompanying drawing, in which:

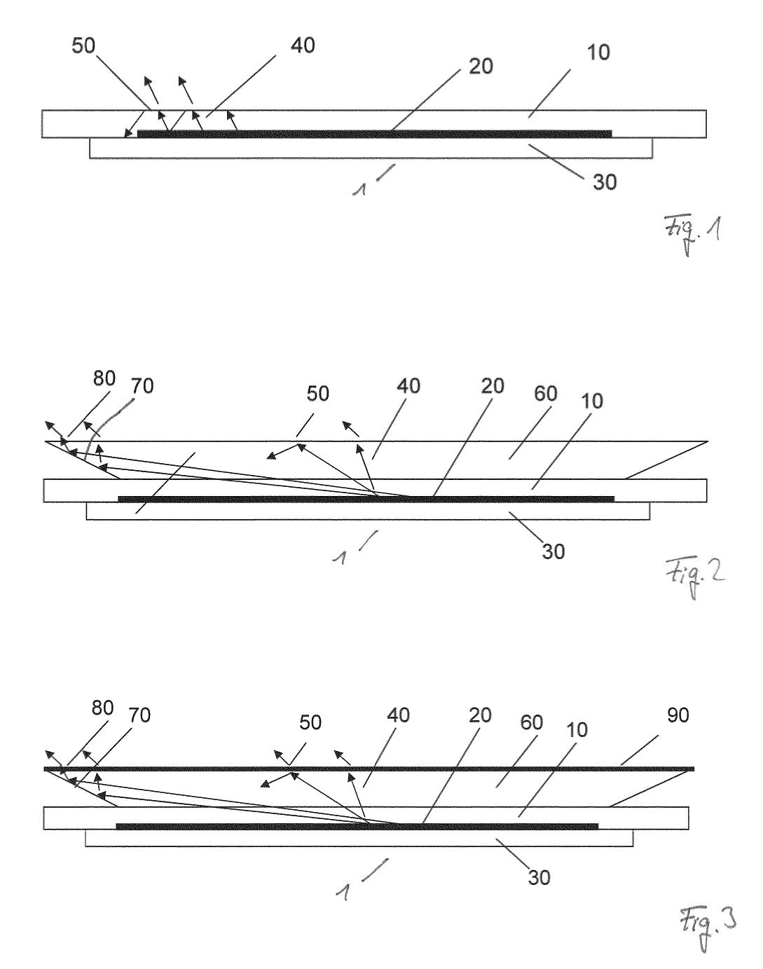

FIG. 1 shows in sectional illustration the construction of a conventional OLED- or QLED-based light module;

FIG. 2 shows a first exemplary embodiment of a light module according to the invention;

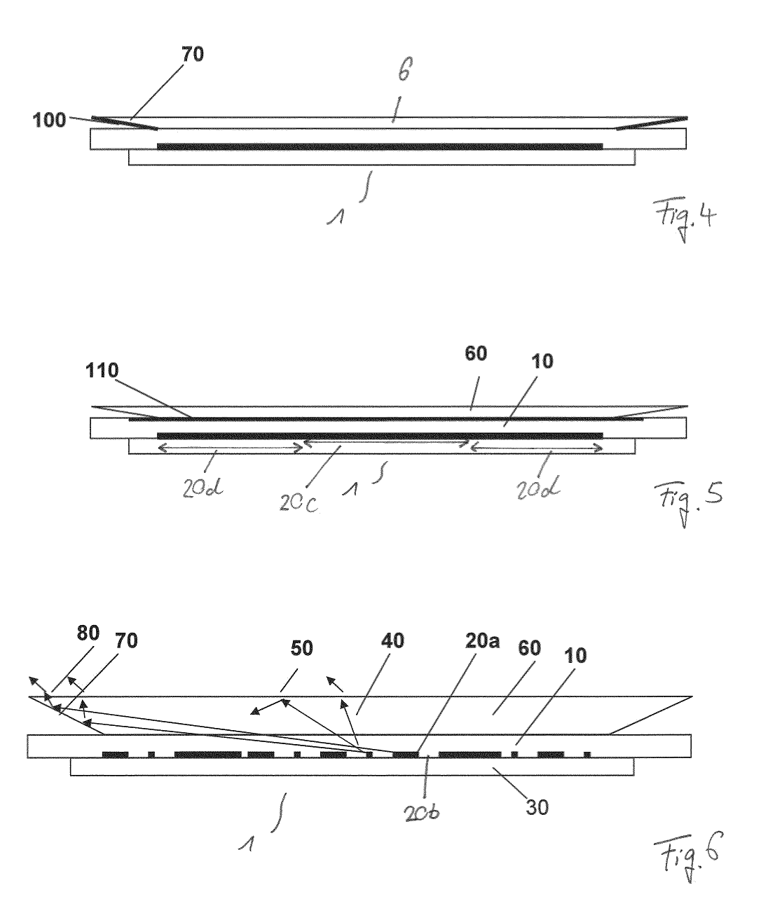

FIGS. 3 to 5 show further exemplary embodiments of a light module according to the invention;

FIG. 6 shows an additional possibility for improving the uniform light emission, and

FIGS. 7a to 7f show different possibilities for the configuration of the edge region of the optical element.

Firstly, the problem addressed by the invention will be explained briefly with reference to FIG. 1. The typical construction of an OLED-based light module 1 is illustrated in cross section, wherein the construction and the solution according to the invention are identical in the case of a QLED light module.

A plate-shaped substrate 10 composed of a light-transmissive material serves as a carrier element of the light module 1. Arranged on the substrate 10 is the active element 20, that is to say the actual OLED having the layer consisting of an organic material, which emits light when a suitable voltage is applied.

A covering element 30 is then in turn arranged at the opposite side 10 relative to the substrate, which covering element can be formed by a cover glass or else, if appropriate, by a light-nontransmissive material. Said covering element 30 protects the active element 20 at its rear side against external influences.

The active element 20 is furthermore also protected at its circumferential region, which can be implemented—as illustrated—for example by virtue of the substrate 10 having a slightly elevated projecting edge region.

As a result, a flat recess is formed in the surface of the substrate 10, into which the active element 20 is embedded, such that the latter is ideally completely protected by the substrate 10 and the cover glass 30. The illustration does not show in this case the required leads for making contact with the electrode layers of the active element 20, although they do not play a significant part for the present invention. As an alternative to the solution illustrated, the active element 20 could furthermore also be protected by a separate frame-like cladding.

The light emission of the module 1 takes place via the substrate 10 in accordance with the arrows illustrated schematically. The light 40 therefore penetrates through the substrate 10, although total internal reflection can occur in part at the interface 50 between the substrate 10 and the surroundings on account of the different refractive indices, particularly if light impinges on the interface 50 at very shallow angles. Part of the light is therefore subjected to total internal reflection at the transition and is lost for the light emission, which leads to a reduced overall efficiency of the light module 1. Furthermore, no light emission will take place in the projecting edge region of the substrate 10, since here the light impinges on the interface 50 only at very shallow angles and is accordingly subjected to total internal reflection as explained above. That is to say that the projecting edge region of the substrate 10 will not be luminous or will have a significantly lower brightness upon activation of the OLED. If a plurality of such light modules 1 are arranged alongside one another, this means that there is in each case a significantly reduced brightness in the transition region between two adjacent light modules.

In order to avoid this problem, the invention proposes fitting an additional optical element at the opposite side of the substrate 10 relative to the active element 20, which optical element enlarges the area over which light is emitted. A first exemplary embodiment in this respect is illustrated in FIG. 2, wherein the additional optical element 60 provided according to the invention is formed by a prism embodied in a trapezoidal fashion in cross section. Said prism has a beveled edge 70 in the edge region or across the circumference, said beveled edge—as illustrated schematically with the aid of the light rays 80—effecting light rays entering the prism 60 at shallow angles by subjecting them to total internal reflection. The reflection at the circumferential edge 70 results in a deflection of said light rays, such that the latter then impinge on the light emission area 50 of the optical element 60 at a new angle, which allows them to leave said optical element.

The use of the optical element 60 therefore has the consequence not only that the light rays normally subjected to total internal reflection at the interface of the substrate 10, which light rays would usually be lost, can now additionally be utilized for the light emission and the efficiency of the light module 1 is accordingly increased, but also that the area over which light is emitted is enlarged. Given corresponding configuration of the optical element 60, therefore, it is possible to obtain a light emission area which corresponds to the area of the substrate 10 with regard to its extent. This means that light emission also takes place in the edge regions of the light module 1 and, accordingly, darker regions no longer occur in the transition regions for the case where a plurality of light modules 1 are arranged alongside one another in a planar fashion. The efficiency and the light emission are therefore significantly improved by the development according to the invention.

Preferably, the optical element 60 or the prism is optically coupled to the substrate 10 in such a way that no influencing occurs upon the transition of the light rays from the substrate 10 into the optical element 60. This can be achieved by virtue of both elements having an approximately identical refractive index.

One development of the basic principle according to the invention is illustrated in FIG. 3, wherein here the light emission area 50 of the optical element 60 is provided with an additional structure 90 or layer. This can involve a diffuser structure 90 or else a microprism structure, which again improves the light emission. Specifically, by virtue of the use of the additional optical element 60, different light exit angles occur at the surface 50 of the prism 60, which has the consequence that a somewhat different emission characteristic could be present in the edge region of the light exit area 50 in comparison with a region directly above the active element 20. The edge region would accordingly still be slightly perceptible from different viewing angles, although this effect is now compensated for by the use of the additional structure 90.

As shown in FIG. 4, a reflective layer 100 can furthermore additionally be provided at the circumferential or edge region of the optical element 60. This measure has the consequence that there are greater freedoms with regard to the configuration of the edge region 70 of the optical element. This is because in this case the edge region 70 no longer has to be coordinated with the required angle of total internal reflection, but rather can be fashioned in a wide variety of ways—as shown in even greater detail below. As shown by a comparison between FIGS. 2 and respectively 3 and 4, the structural height of the optical element 60 can be reduced by this measure, such that the entire construction of the light module 1 can be made very flat. In this case, the additionally reflective layer 100 can have both a diffusely scattering and a specularly reflective behavior.

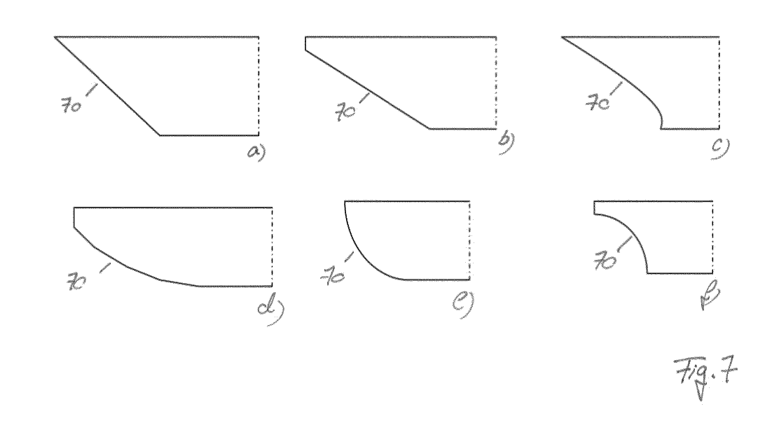

Finally, as a further additional measure, shown in FIG. 5, an additional diffuser layer 110 can be introduced in the transition region between substrate 10 and optical element 60. On account of the property of OLEDs of emitting light with different color loci in part preferably in different spatial directions, the problem could arise that the edge region of the optical element 60 in part emits light in a different color. This effect is in turn compensated for or balanced by the diffuser layer 110, such that ultimately a uniform, homogeneous light emission across the entire area of the optical element 60 is obtained.

It should be mentioned that the measures which are illustrated in FIGS. 3 to 5 and which further optimize the light emission of the light module 1 can of course be used independently of one another—as illustrated—or can be combined with one another in any desired manner.

An additional possibility for further improving the light emission is illustrated in FIG. 6, wherein the development explained below can in turn be combined with all measures described above.

In the case of the exemplary embodiment in accordance with FIG. 6, the active element 20—in contrast to previously—does not form a closed area that is driven uniformly. Instead, the active element 20 is structured in such a way that it is subdivided in its area into a plurality of luminous regions 20a and non-luminous regions 20b. This structuring can be carried out by means of a corresponding matrix, although the luminous regions 20a are preferably once again driven uniformly.

The uniformity of the light emission can now be further improved by means of a corresponding structuring of the area, in particular a suitable choice of the density of the luminous regions 20a. The reason for this measure is that a different luminance occurs within the luminous area in the case of OLEDs or QLEDs in part on account of corresponding current density distributions. In other words, an OLED is often less brightly luminous in a central region of the area than at the edge, which inter alia is also attributable to the non-optimum conductivity of the transparent electrode layers used in the OLED. This effect is now compensated for in the case of the development in accordance with FIG. 6 by virtue of the density of the luminous regions being increased in those regions in which a lower luminance would usually be present. As can be discerned from the illustration in FIG. 6, larger gaps between the luminous regions 20a, that is to say larger non-luminous regions 20b are provided in the edge region and ultimately provide for the compensation sought to the effect that the brightness of the active element 20 as viewed across its entire area is substantially identical. The use of the light-scattering means already mentioned above can then prevent the structuring of the active element 20 from being discernible to an observer, that is to say different luminous or non-luminous regions from being individually perceptible.

As an alternative thereto, it would also be conceivable to subdivide the active element 20 into a plurality of regions that are drivable separately from one another and to perform driving of said regions in such a way that a uniform brightness is in turn present. This concept is indicated in FIG. 5, wherein here provision is made for subdividing the active element 20 into a central region 20c and a frame-like edge region 20d. Both regions 20c and 20d can, as already mentioned, by driven separately from one another, wherein now the driving is in turn chosen in such a way that a brightness that is as uniform as possible is present as viewed across the entire area. This variant, too, can be combined with the additional optical measures mentioned above.

As already mentioned, in particular for the case where the circumferential region 70 of the optical element is configured in a reflective fashion, the region can be designed very freely with regard to its contour.

FIGS. 7a to 7f show conceivable variants for the configuration of the edge region, wherein in principle the advantage is afforded that impinging light rays are deflected in such a way that they can leave the light emission area of the optical element 60 in the edge region thereof. In this case, some of the edge regions are distinguished by the fact that they can be realized comparatively simply, and others allow a somewhat better control of the deflection of the light rays.

Ultimately, therefore, the efficiency and quality of the light emission in a light module are significantly optimized by means of the measures according to the invention. By means of comparatively simple measures, it is now possible to provide light modules which emit light homogeneously right into the edge region, such that in particular a plurality of such modules can also be combined with one another in a planar fashion in order to realize an arrangement that emits light over a large area. In this case, the concept according to the invention is applicable both to OLED light modules and to QLED light modules.

1. A light module, comprising:
a plate-shaped active element, formed by an OLED or QLED,
a plate-shaped, light-transmissive carrier element having a surface on which the active element is arranged, wherein the carrier element has an edge region that projects with respect to the active element,
an optical element, which is arranged on an opposite side of the carrier element relative to the active element and is designed to form a light emission area of the light module, which light emission area is extended relative to the area of the active element,
wherein the optical element is embodied in a plate-like fashion having a light entrance area facing the carrier element and the light emission area opposite the light entrance area, wherein the light emission area has a larger extent than the light entrance area,
wherein, the side regions connecting the two flat sides of the optical element are provided with a reflective layer.

2. The light module as claimed in claim 1, wherein the reflective layer is diffusely reflective.

3. The light module as claimed in claim 1, wherein the light exit area corresponds to the area of the carrier element with regard to its extent.

4. The light module as claimed in claim 1, wherein the light entrance area of the optical element substantially corresponds to the area of the active element with regard to its extent.

5. The light module as claimed in claim 1, wherein the optical element is embodied in a trapezoidal or frustoconical fashion in cross section.

6. The light module as claimed in claim 1, wherein the side regions connecting the two flat sides of the optical element have a curvature.

7. The light module as claimed in claim 1, wherein a diffuser layer is arranged between the carrier element and the optical element.

8. The light module as claimed in claim 1, wherein the light exit area of the optical element is provided with a light-influencing structure.

9. The light module as claimed in claim 8, wherein the structure is a scattering structure or a prism structure.

10. The light module as claimed in claim 8, wherein the active element is subdivided into a plurality of luminous and non-luminous regions, wherein the luminous regions are preferably uniformly drivable.

11. The light module as claimed in claim 10, wherein the active element has a higher density of luminous regions in a central region than in an edge region.

12. The light module as claimed in claim 1, wherein the active element is subdivided into at least two regions which are drivable separately from one another.

13. The light module as claimed in claim 12, wherein the active element is subdivided into a central region and an edge region, which is drivable separately therefrom.
